(19) United States
(12) Patent Application Publication
(10) Pub. No.: US 2011/0062964 A1
(43) Pub. Date: Mar. 17, 2011

(54) METHOD AND APPARATUS FOR MEASURING SURFACE PROPERTIES

(76) Inventors: Yoshihiro Hosokawa, Kyoto-shi (JP); Kei Kobayashi, Kyoto-shi (JP); Hirofumi Yamada, Kyoto-shi (JP); Kazumi Matsushige, Kyoto-shi (JP); Yukiko Mori, Kyoto-shi (JP)

(21) Appl. No.: 12/991,309

(22) PCT Filed: Apr. 30, 2009
(86) PCT No.: PCT/JP2009/001980

§ 371 Date: Nov. 5, 2010

(30) Foreign Application Priority Data
May 9, 2008 (JP) 2008-123953

(51) Int. Cl. G01R 27/32

(52) U.S. Cl. 324/635

(57) ABSTRACT

A method for measuring surface properties according to the present invention includes the steps of: with distance control feedback applied so that a desired physical quantity to be measured that is attributed to an interaction between a probe and a sample is actually measured while changing a measured distance between the probe and the sample in accordance with a relationship between the desired physical quantity and the measured distance, (i) setting a set value, corresponding to the desired physical quantity, which serves to change the measured distance; and (ii) recording, for each set value thus set, a relationship between the measured distance changed by the set value set in the step (i) and a physical quantity measured with the probe and the sample placed at that measured distance. This allows precise and quick measurement of a physical quantity even in a region where the probe and the sample are very close to each other, while avoiding a collision between them.

### TECHNICAL FIELD

The present invention relates to: a method for measuring surface properties, which measures the surface properties of a sample by placing a probe in close proximity to a surface of the sample; and an apparatus for measuring surface properties, which measures the surface properties of a sample by using such a method.

### BACKGROUND ART

Conventionally, a scanning atomic force microscope (AFM) using atomic force acting between a probe and a surface of a sample has been known as a scanning probe microscope. The AFM includes: a probe; a cantilever, which supports the probe; and a displacement measuring system, which detects a bend in the cantilever. The AFM allows observation of the surface shape of a sample by detecting action force Fts (attractive force or repulsive force) between the probe and the sample. This AFM makes it possible to obtain local information about a surface of an atom, a molecule, an organic molecule, or a non-conducting substance such as an insulator. The AFM observation makes it possible to measure a surface shape in various modes such as a contact mode and a dynamic mode.

The term “cantilever” here means a rectangular or triangular plate spring having a minute probe fixed thereto. Assuming that its longitudinal direction is an X direction, that its transverse direction is a Y direction, and that the direction in which the probe and the sample face each other is a Z direction, the distance D between the probe of the cantilever and the sample can be rephrased as the position of the probe of the cantilever along the Z direction. A reason why the AFM controls the position of the probe along the Z direction, i.e., the displacement of the cantilever along the Z direction is that the surface of the sample cannot be accurately measured unless the distance D is constant. In order to hold the distance D constant, the AFM always detects the action force Fts acting between the probe and the sample and controls the distance D so that the action force Fts always takes on a set value. This control is called probe-to-sample distance control feedback.

In general, an AFM has a function of measuring a force curve that represents a relationship between the action force Fts acting between the probe of the cantilever and a sample and the distance D. In the conventional measurement of a force curve, a change in action force Fts relative to the distance D is obtained by turning off the aforementioned probe-to-sample distance control feedback with the distance D between the probe and the sample held constant, changing the distance D, and measuring the action force Fts.

FIG. 6 shows a force curve obtained by the conventional method. The horizontal axis represents the distance D (nm) between the probe of the cantilever and the sample, and the left side of its reference position (which corresponds to 0 on the horizontal axis) indicates a direction in which the probe and the sample move toward each other and the right side indicates a direction in which the probe and the sample move away from each other. The vertical axis represents the action force Fts between the probe and the sample as an amount of change in resonant frequency of the cantilever, i.e., as a frequency shift amount (Hz), and indicates that the action force becomes larger as it goes downward in FIG. 6. As shown in FIG. 6, the smaller the distance D becomes, the larger the action force Fts between the probe and the sample becomes. Moreover, because a region where the distance D is smaller (region surrounded by an oval in FIG. 6) is a region that is very important in evaluating properties, it is known to be important to obtain a force curve in that region.

Patent Document 1 describes a method for obtaining a force curve, which detects the displacement of a probe of a cantilever due to action force Fts acting between the probe and a sample and, at the same time, controls the operation of an actuator in accordance with the displacement. This method prevents the sample from being pressed against the probe more than necessary when the probe and the sample are moved toward each other and prevents the sample from being excessively adsorbed to the probe when the sample and the probe are set apart from each other.

Patent Document 2 describes a method for obtaining a force curve, which uses an amount of deflection to designate a range in which a force curve is measured and prevents the action of excessive force by keeping the action force Fts to be measured within the limits of set values.

Patent Document 3 designates, as a range in which a force curve is measured, the maximum and/or minimum value(s) of action force Fts acting between a probe of a cantilever and a sample, sets the number of measurements N, changes the distance D between the probe of the cantilever and the sample within a range of the maximum and/or minimum value(s), and measures the action force Fts. This method allows the action force to act on the sample within the range from the maximum action force and the minimum action force, thereby preventing the generation of excessive action force.

However, the conventional methods for obtaining a force curve may suffer from a collision of a probe with a sample in cases where the distance D between the probe and the sample is unintentionally changed by the influence of a drift or the like when a surface shape is measured in the contact mode or the dynamic mode. If the sample is a very soft, the sample is undesirably destroyed by the pressure force of the probe. Alternatively, if the sample is hard, the probe is undesirably destroyed.

The methods for obtaining a force curve as described in Patent Documents 1, 2, and 3 have suffered from such a problem as follows: Because a range of measurement of a force curve is set by designating the position of a probe of a cantilever or the position of a sample or the amount of deflection in the cantilever, the probe and the sample collide with each other in cases where there occurs a shift in position from the designated position due to a temperature drift, a vibration drift, or the like, with the result that both of them are damaged. Moreover, the shift in position causes a distortion in the force curve, thereby making it impossible to obtain an accurate force curve. Alternatively, in a region where a change in action force Fts relative to a change in distance D between the probe and the sample is very big, i.e., in a region where the probe and the sample are at a short distance from each other (region that is very important in evaluating properties), the action force Fts changes greatly in response to a minute change in distance D; therefore, it is difficult to obtain a precise force curve.

In the case of measurement of a force curve in a region where the probe and the sample are very close to each other, the method for obtaining a force curve as described in Patent Document 3 may suffer from such a problem as follows: Because the slope of the force curve is steep in the region and the probe is set to proceed the same distance for each measurement, it is necessary to increase the number of measurements N in order to avoid a collision between the probe and the sample. Such an increase leads to an increase in measuring time. To that extent, the distance D becomes prone to be influenced by a drift. This causes the probe and the sample to collide with each other, with the result that both of them are damaged.

Alternatively, the methods for obtaining a force curve as described in Patent Documents 1, 2, and 3 may suffer from a collision between a probe and a sample due to a creep. The term “creep” means a phenomenon where the probe does not quickly stop moving due to a delay in response to a signal (application of a voltage). In a region where the probe and the sample are very close to each other, such a creep may pose a risk of a collision between the probe and the sample. In particular, according to the method for obtaining a force curve as described in Patent Document 3, it is necessary to increase the number of measurements N in an attempt to measure such a steep region. In that case, it takes a longer time to measure a force curve; therefore, a drift becomes likely to occur. On the other hand, in the case of an attempt to suppress the occurrence of a drift by reducing the amount of measuring time required for each measurement, there is an increase in number of times a signal is transmitted per unit time, and such an increase leads to an increase in frequency of collisions between the probe and the sample due to the generation of a creep.

Moreover, the aforementioned various problems may also occur when a property that is measured between a probe and a sample, such as a local tunneling current, a local surface potential, or local magnetic force, is measured, as well as when a force curve is obtained.

### CITATION LIST

Patent Document 1

Japanese Patent Application Publication, No. H8-201406 (Publication Date: Aug. 9, 1996)

Patent Document 2

Japanese Patent Application Publication, No. 2000-346782 (Publication Date: Dec. 15, 2000)

Patent Document 3

Japanese Patent Application Publication, No. 2000-180340 (Publication Date: Jun. 30, 2000)

### SUMMARY OF INVENTION

The present invention has been made in view of the foregoing problems, and it is an object of the present invention to provide: a method for measuring surface properties, which makes it possible to precisely and quickly measure surface properties even in a region where a probe and a sample are very close to each other; and an apparatus for measuring surface properties, which measures the surface properties of a sample by using such a method.

In order to solve the foregoing problems, a method for measuring surface properties according to the present invention is a method for measuring surface properties, which measures surface properties of a sample by placing a probe in close proximity to a surface of the sample, the method including the steps of: with distance control feedback applied so that a desired physical quantity to be measured that is attributed to an interaction between the probe and the sample is actually measured while changing a measured distance between the probe and the sample in accordance with a relationship between the desired physical quantity and the measured distance, (i) setting a set value, corresponding to the desired physical quantity, which serves to change the measured distance; and (ii) recording, for each set value thus set, a relationship between the measured distance changed by the set value set in the step (i) and a physical quantity measured with the probe and the sample placed at that measured distance.

Further, in order to solve the foregoing problems, an apparatus for measuring surface properties according to the present invention is an apparatus for measuring surface properties, which measures surface properties of a sample by placing a probe in close proximity to a surface of the sample, the apparatus including: feedback control means for applying distance control feedback so that a desired quantity to be measured that is attributed to an interaction between the probe and the sample is actually measured while changing a measured distance between the probe and the sample in accordance with a relationship between the desired physical quantity and the measured distance; setting means for setting a set value, corresponding to the desired physical quantity, which serves to change the measured distance; and recording means for recording, for each set value thus set, a relationship between the measured distance changed by the set value set by the setting means and a physical quantity measured with the probe and the sample placed at that measured distance, with the feedback control means applying the distance control feedback.

According to the method and apparatus for measuring surface properties according to the present invention thus configured, a set value, corresponding to a desired physical quantity, which serves to change a measured distance between a probe and a sample is set, and the measured distance is feedback-controlled so that the desired physical quantity is actually measured in correspondence with the set value. Moreover, after the distance between the probe and the sample has been controlled in correspondence with a set value, still another set value is set, then the distance between the probe and the sample is controlled accordingly. Thus, a relationship between the measured distance and a physical quantity measured with the probe and the sample placed at that measured distance is recorded for each set value.

Thus, the method and apparatus for measuring surface properties according to the present invention control the measured distance between the probe and the sample in correspondence with a set value corresponding not to the measured distance but to a desired physical quantity. Therefore, in a region where the slope of a force curve is steep in a relationship between the physical quantity and the measured distance, the amount of change in measured distance per unit time can be reduced by appropriately setting a set value, whereby a collision between the probe and the sample due to a creep can be avoided. Further, in a region about which no particular information is required in a relationship between the physical quantity and the measured distance, the amount of time to measure a physical quantity can be reduced by appropriately setting a set value. As a result, the frequency at which an influence is exerted by a temperature drift, a vibration drift, or the like is reduced, whereby a collision between the probe and the sample can be prevented.

Therefore, for example, in cases where the method for measuring surface properties according to the present invention is used for obtaining a force curve as described later, the measured distance can be controlled by appropriately setting a set value. This makes it possible to obtain a steeply sloping force curve even in a region where such a force curve was not be able to be obtained by a conventional method (region that is very important in evaluating properties). Moreover, because the measured distance is controlled in accordance with the set value, a collision between the probe and the sample is avoided as mentioned above. Further, even in the case of occurrence of an unintended change in distance due to a drift or the like, a collision between the probed and the sample is avoided, because the measured distance is controlled in accordance with the set value.

Thus configured, the method and apparatus for measuring surface properties according to the present invention allow precise and quick measurement of the surface properties of a sample even in a region where the probe and the sample are very close to each other and, as such, make it possible to obtain information about the local properties of a surface of the sample that has not been obtainable conventionally.

As described above, a method for measuring surface properties according to the present invention includes the steps of: with distance control feedback applied so that a desired physical quantity to be measured that is attributed to an interaction between a probe and a sample is actually measured while changing a measured distance between the probe and the sample in accordance with a relationship between the desired physical quantity and the measured distance, (i) setting a set value, corresponding to the desired physical quantity, which serves to change the measured distance; and (ii) recording, for each set value thus set, a relationship between the measured distance changed by the set value set in the step (i) and a physical quantity measured with the probe and the sample placed at that measured distance.

Further, as described above, an apparatus for measuring surface properties according to the present invention includes: feedback control means for applying distance control feedback so that a desired quantity to be measured that is attributed to an interaction between a probe and a sample is actually measured while changing a measured distance between the probe and the sample in accordance with a relationship between the desired physical quantity and the measured distance; setting means for setting a set value, corresponding to the desired physical quantity, which serves to change the measured distance; and recording means for recording, for each set value thus set, a relationship between the measured distance changed by the set value set by the setting means and a physical quantity measured with the probe and the sample placed at that measured distance, with the feedback control means applying the distance control feedback.

This allows precise and quick measurement of a physical quantity even in a region where the probe and the sample are very close to each other, while avoiding a collision between them.

### BRIEF DESCRIPTION OF DRAWINGS

FIG. 1 is a conceptual diagram of a method for obtaining a force curve according to the present embodiment.

FIG. 2 shows a force curve that is obtained by the method for obtaining a force curve according to the present embodiment.

FIG. 3 is a schematic diagram of a sample hold circuit.

FIG. 4 is a conceptual diagram of another method for obtaining a force curve according to the present embodiment.

FIG. 5 is a conceptual diagram of still another method for obtaining a force curve according to the present embodiment.

FIG. 6 shows a force curve measured by a conventional method.

### DESCRIPTION OF EMBODIMENTS

A method for measuring surface properties according to the present embodiment can be applied, for example, to measuring a local tunneling current, measuring a local surface potential, measuring local magnetic force, and the like, as well as measuring a force curve. In this case, a property value that is measured between a probe and a sample is a current, a voltage, or magnetism attributed to an interaction between the probe and the sample. Further, in the measurement of a local tunneling current, such various combinations are possible as measuring the value of a current and, at the same time, carrying out distance control by carrying out distance control feedback between the probe and the sample by force acting between the probe and the sample. Further, an apparatus for measuring surface properties according to the present embodiment can be applied to various scanning atomic force microscopes such as those based on a probe vibration amplitude detecting scheme, those based on a probe deflection detecting scheme, and those based on a probe vibration phase detecting scheme, as well as those based on a probe vibration frequency modulation detecting scheme, other scanning microscopes, and apparatuses for measuring local properties by using probes.

In this light, the method and apparatus for measuring surface properties according to the present embodiment are described in detail by taking as an example a method for measuring a force curve using a scanning atomic force microscope based on the probe vibration frequency modulation detecting scheme.

### Embodiment 1

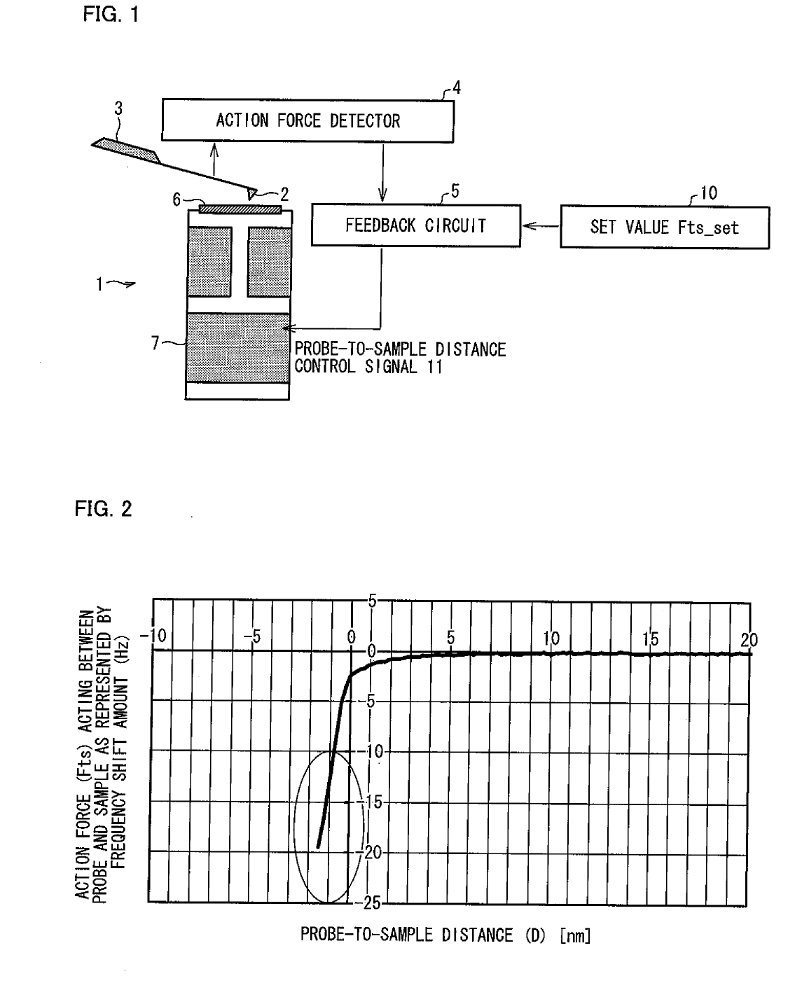

The present embodiment is described below with reference to FIGS. 1 through 3.

FIG. 1 is a conceptual diagram of a method for obtaining a force curve according to the present embodiment. Scanning atomic force microscope 1 of FIG. 1 includes: probe 2; cantilever 3, which supports the probe 2; action force detector 4, which detects, as a resonant frequency, action force Fts acting between probe 2 and sample 6; feedback circuit 5, into which the action force Fts detected by action force detector 4 is inputted as a voltage value; and PZT scanner 7, which uses a piezoelectric element to move sample 6 along the Z axis, the X axis, and the Y axis in accordance with probe-to-sample distance control signal 11 (control signal). Scanning atomic force microscope 1 allows observation of the surface shape of sample 6 by detecting the action force Fts between probe 2 and sample 6.

Because action force detector 4 cannot detect the action force Fts per se, action force detector 4 detects a variation in resonance frequency of cantilever 3 as a physical quantity that reflects the action force Fts; however, it is possible to employ any other detecting scheme.

Into feedback circuit 5, a set value (Fts_set) 10 (set value), as well as the variation in resonant frequency of cantilever 3 as detected by action force detector 4, is inputted as a voltage value. Set value (Fts_set) 10 is inputted so that the action force Fts between probe 2 and sample 6 is kept as action force corresponding to the set value, and is inputted as a voltage value. That is, by inputting the set value into feedback circuit 5, the variation in resonant frequency of cantilever 3 is controlled. This operation will be described in detail later.

PZT scanner 7 is a mechanism that uses a piezoelectric element to scan sample 6. In the present embodiment, the piezoelectric element is made of PZT (lead zirconate titanate), which is a type of ceramic; however, it is possible to use a scanner made of any other material.

A method for obtaining a force curve according to the present embodiment thus configured is described below with reference to FIG. 1.

First, at the start of measurement, the distance (measured distance) between probe 2 and sample 6 is set so that probe 2 and sample 6 are placed at any usual distance from each other. Next, with probe 2 and sample 6 placed at that distance, action force detector 4 is used to detect action force Fts between probe 2 and sample 6. As mentioned above, since the action force Fts is not detected per se, a variation in resonant frequency of cantilever 3 is detected as a physical quantity that reflects the action force Fts. The variation in resonant frequency thus detected by action force detector 4 is converted into a voltage value in action force detector 4, and the voltage value is then inputted into feedback circuit 5.

Furthermore, into feedback circuit 5, set value (Fts_set) 10 is inputted. Set value (Fts_set) 10 is inputted so that the action force Fts between probe 2 and sample 6 is kept as action force corresponding to the set value, and is inputted as a voltage value. It should be noted that set value (Fts_set) may be set by a setting section (setting means; not shown) provided inside or outside of PZT scanner 7.

Thus, into feedback circuit 5, the voltage value, into which the variation in resonant frequency of cantilever 3 has been converted, and set value (Fts_set) 10 are inputted. It should be noted that there is a predetermined range of set values (Fts_set) 10, and a predetermined value falling within that determined range is inputted into feedback circuit 5.

Next, feedback circuit 5 outputs probe-to-sample distance control signal 11 in accordance with set value (Fts_set) 10 inputted into feedback circuit 5. Probe-to-sample distance control signal 11 is a signal that controls the distance D between probe 2 and sample 6 so that the action force Fts is equal to action force corresponding to set value (Fts_set) 10. That is, probe-to-sample distance control signal 11 is a signal, generated in accordance with set value (Fts_set) 10, which controls the distance between probe 2 and sample 6.

Therefore, probe-to-sample distance control signal 11 is inputted into PZT scanner 7, and PZT scanner 7 scans sample 6 in accordance with the signal, so that probe 2 and sample 6 are placed at such a distance from each other that the action force between probe 2 and sample 6 is equal to the action force corresponding to set, value (Fts_set) 10.

After that, the variation in resonant frequency of cantilever 3, which is equivalent to the action force Fts corresponding to set value (Fts_set) 10), is detected by action force detector 4, and the detected value is inputted into feedback circuit 5. Then, into feedback circuit 5, another set value (Fts_set) 10 different from the previous one is inputted, and new probe-to-sample distance control signal 11 is generated in accordance with that set value (Fts_set) 10. Alternatively, feedback circuit 5 may be configured to make a comparison between the variation in resonant frequency as inputted into feedback circuit 5 and a variation in resonant frequency equivalent to set value (Fts_set) 10 and, when they are equal, receive another set value (Fts_set) 10 different from the previous one. In the present embodiment, these operations are referred to as feedback. It should be noted that, as evidenced by the description above, set value (Fts_set) 10 is set in correspondence with the desired action force to be measured, regardless of a variation in resonant frequency as measured immediately before the set value is set or, in other words, independently of a variation in resonant frequency as measured immediately before the set value is set.

The subsequent operations are the same as those described above: After new set value (Fts_set) 10 is inputted, action force Fts corresponding to that set value (Fts_set) 10 is set. That is, this series of operations is carried out with the distance control feedback applied. Therefore, the action force Fts that a user would like, set value (Fts_set) 10 corresponding to the action force Fts, and the distance between probe 2 and sample 6 that is controlled by set value (Fts_set) 10 can be said to be associated with each other.

Thus, in the present embodiment, as set values (Fts_set) 10 are inputted into feedback circuit 5 with the distance control feedback applied, the distance between probe 2 and sample 6 changes. Then, for each of set values (Fts_set) 10, a relationship between the distance and a physical quantity measured with probe 2 and sample 6 placed at that distance is recorded; and in accordance with a relationship between the distance and a variation in resonant frequency, a force curve that represents a relationship between the distance and action force Fts between probe 2 and sample 6 is obtained. It should be noted that the relationship between the distance between probe 2 and sample 6 and the measured physical quantity may be recorded by a recording section (recording means) provided inside or outside of PZT scanner 7. Moreover, a display section (not shown) or the like displays the relationship between the distance and the measured physical quantity as recorded by the recording section, so that the user can confirm the obtained force curve.

An effect of obtaining a force curve with the distance control feedback applied during the operation is described below with reference to FIGS. 1 through 3.

The method for obtaining a force curve according to the present embodiment makes it possible to appropriately change set values (Fts_set) 10 and thereby obtain a steeply sloping force curve even in a region where such a force curve was not be able to be obtained by a conventional method (region that is very important in evaluating properties). At the same time, the range of set values (Fts_set) 10 is determined in advance, and the distance D is automatically controlled through the use of the distance control feedback; therefore, a collision between probe 2 and sample 6 can be avoided.

Moreover, in a region where the slope of a force curve is steep, the amount of change in distance D per unit time can be automatically reduced. That is, even with the same amount of change in set value (Fts_set) 10, the amount of change in distance D for each measurement changes slowly in the region where the slope of the force curve is steep and changes rapidly in a region where the slope of the force curve is gentle, in accordance with the amount of change (slope of the force curve) in action force Fts relative to the distance D. This makes it possible to reduce the amount of time to measure a force curve in a region about which no particular information is required and thereby reduce the total amount of measuring time. Moreover, the reduction in measuring time makes it possible to reduce the frequency at which an influence is exerted by a drift, whereby a collision between probe 2 and sample 6 can be avoided. Further, since set values (Fts_set) 10 can be appropriately changed and the force curve is measured slowly in the region where its slope is steep, a collision between probe 2 and sample 6 due to a creep can be prevented.

FIG. 2 shows a force curve obtained through scanning atomic force microscope 1. As indicated by a region surrounded by an oval in FIG. 2, the method for obtaining a force curve according to the present embodiment makes it possible to obtain a force curve in a region where a force curve was not be able to be obtained conventionally (e.g., a region where the frequency shift amount is approximately −20 Hz). This is an effect that can be first realized by the aforementioned effect, i.e., the distance control feedback by which to change set values (Fts_set) 10 within a predetermined range, automatically control the distance D along with the changes, and detect action force Fts equivalent to the distance D. This makes it possible to precisely measure a force curve even in a region where the slope of the force curve is steep. Furthermore, as mentioned above, in a region where the slope of a force curve is steep, the amount of change in distance D per unit time can be automatically reduced. Therefore, in the steep region, a larger number of measuring points can be put than in a region that is not steep. Since the steep region is a region that is very important in evaluating properties, more information can be obtained about the properties of the sample by putting a larger number of measuring points in the region.

Furthermore, since the method for obtaining a force curve according to the present embodiment automatically controls the distance D between probe 2 and sample 6 through the use of the distance control feedback, it advantageously eliminates the need for the use of a sample hold circuit.

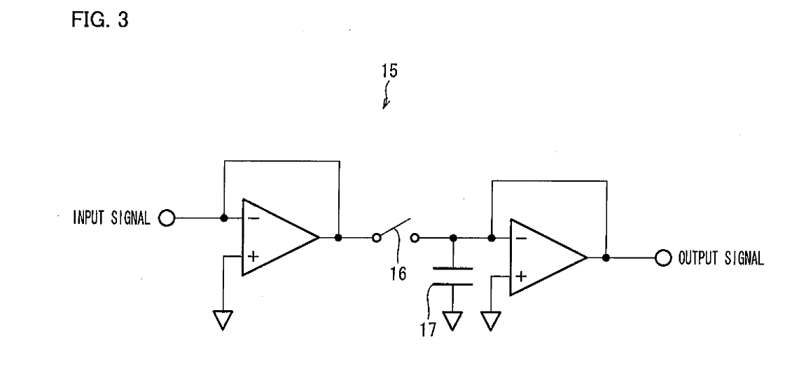

The term “sample hold circuit” means a circuit that extracts an analog signal for sampling and holds it for a certain period of time. A sample hold circuit is described here with reference to FIG. 3. FIG. 3 is a schematic diagram of a sample hold circuit. Sample hold circuit 15 includes analog switch 16 and capacitor 17. After analog switch 16 is turned on and capacitor 17 is charged with an input signal, analog switch 16 is turned off and the voltage with which capacitor 17 has been charged is held. In this state of things, the voltage stored in capacitor 17 holds predetermined information.

However, in sample hold circuit 15, if analog switch 16 is kept turned off, capacitor 17 gradually releases charges. Then, the release of charges from the capacitor causes a change in content of the information. Such a phenomenon where leakage of a current from a capacitor causes a change in hold voltage is called “droop of a circuit”, and droop may cause a change in content of information held in the capacitor.

In a conventional scanning atomic force microscope including a sample hold circuit, information about the position of the probe at some point in time has been held as a hold voltage stored in the capacitor. Because of such gradual release of charges from the capacitor as mentioned above, there has been such a problem as a change in information about the position of the probe. That is, there has been such a seemingly drift-like problem that the probe shifts its position from the initial position over time. As a result, there has been such a problem that droop causes the probe and the sample to collide with each other, with the result that both of them are damaged, or makes it impossible to measure an accurate force curve.

In this regard, since the method for obtaining a force curve according to the present embodiment automatically controls the distance D between probe 2 and sample 6 through the use of the distance control feedback, it eliminates the need for the use of a sample hold circuit. Therefore, there occurs no droop as has been a problem with the conventional method for obtaining a force curve, nor does there occur any shift in position of probe 2 due to such droop. That is, the method for obtaining a force curve according to the present embodiment allows more precise measurement of a force curve than the conventional method for obtaining a force curve.

Thus, since the method for obtaining a force curve according to the present embodiment automatically controls the distance between probe 2 and sample 6 through the use of the distance control feedback, it can overcome the aforementioned conventional problems and, as a result, allows precise and quick measurement of a force curve even in a region where probe 2 and sample 6 are very close to each other. Conventionally, a force curve has been obtained by setting upper and lower limits on the action force Fts instead of using feedback control. That is, the method for obtaining a force curve according to the present embodiment overcomes the aforementioned conventional problems by adopting a totally unconventional approach.

### Embodiment 2

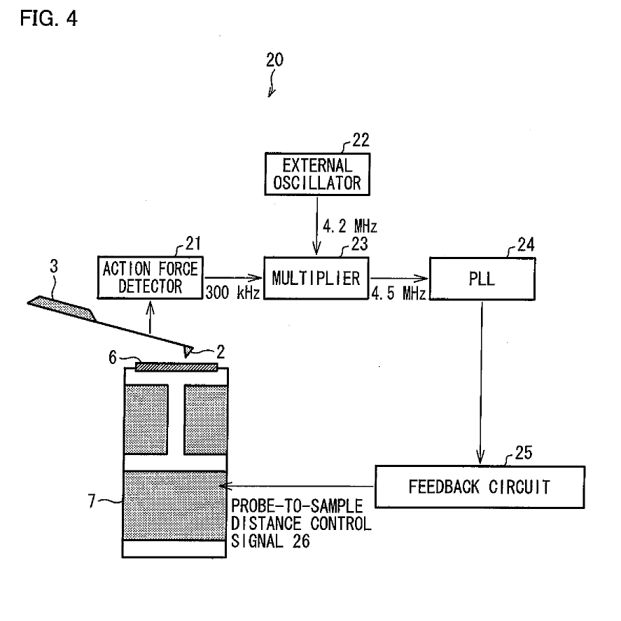

Embodiment 2 is described below with reference to FIG. 4. In FIG. 4, components identical to those described with reference to FIG. 1 are given the same reference numerals. Therefore, those components are not described in detail below.

FIG. 4 is a conceptual diagram of another method for obtaining a force curve according to the present embodiment. Scanning atomic force microscope 20 of FIG. 4 includes: probe 2; cantilever 3, which supports probe 2; action force detector 21, which detects, as a resonant frequency, action force Fts acting between probe 2 and sample 6; PZT scanner 7, which uses a piezoelectric element to move sample 6 along the Z axis, the X axis, and the Y axis in accordance with probe-to-sample distance control signal 26 (control signal); external oscillator 22, multiplier 23, PLL 24; and feedback circuit 25.

External oscillator 22 produces a variable external frequency, and the external frequency is inputted into multiplier 23. Multiplier 23 converts the resonant frequency of cantilever 3 as detected by action force detector 21 into a frequency that is a sum of or difference between the resonant frequency and the external frequency outputted from external oscillator 22, and then outputs the converted frequency to PLL 24. PLL 24 converts the converted frequency as outputted from multiplier 23 into a voltage through a phase lock loop, and then outputs the voltage to feedback circuit 25. Feedback circuit 25 makes a comparison between the voltage value corresponding to the resonant frequency of the cantilever as outputted from PLL 24 and a predetermined standard voltage (set value), generates probe-to-sample distance control signal 26 in accordance with a result of the comparison, and then outputs probe-to-sample distance control signal 26 to PZT scanner 7. It should be noted that the standard voltage may be set in feedback circuit 25 through a setting section (not shown). Further, the standard voltage to be set is set in correspondence with the desired action force to be measured, regardless of a variation in resonant frequency as measured immediately before the standard voltage is set or, in other words, independently of a variation in resonant frequency as measured immediately before the set value is set.

A method for obtaining a force curve according the present embodiment thus configured is described below with reference to FIG. 4. It should be noted that operations identical to those carried out in scanning atomic force microscope 1 described with reference to FIG. 1 are not described in detail below. Further, for convenience of explanation, the present embodiment is described with reference to specific numerical values. However, the present embodiment is not limited to those values and, needless to say, can be varied in many ways.

First, at the start of measurement, the distance between probe 2 and sample 6 is set so that probe 2 and sample 6 are placed at any usual distance from each other. Next, with probe 2 and sample 6 placed at that distance, action force detector 21 is used to detect action force Fts between probe 2 and sample 6. As mentioned above, since the action force Fts is not detected per se, the resonant frequency of cantilever 3 is detected as a physical quantity that reflects the action force Fts. The resonant frequency thus detected by action force detector 21 is then inputted into multiplier 23. In the present embodiment, the resonant frequency of cantilever 3 thus detected is 300 kHz. Furthermore, multiplier 23 receives a variable external frequency from external oscillator 22. Since the external frequency is variable, it is possible to choose any external frequency. However, in the present embodiment, multiplier receives a frequency of approximately 4.2 MHz. The present embodiment is described on the assumption that a predetermined reference value for the output voltage value of PLL 24 is 5 V.

As mentioned above, multiplier 23 receives the resonant frequency of 300 kHz of cantilever 3 and the external frequency of approximately 4.2 MHz, multiplies them to obtain a frequency of approximately 4.5 MHz, and inputs the frequency into PLL 24. PLL 24 outputs a voltage value corresponding to the input frequency, and inputs the output into feedback circuit 25. In the present embodiment, when the input frequency into PLL 24 is 4.5 MHz, the output voltage value of PLL 24 is 5 V.

Feedback circuit 25 confirms whether or not the voltage value outputted from PLL 24 matches the predetermined reference value. If it does not match, feedback circuit 25 generates probe-to-sample distance control signal 26 to change the distance between probe 2 and sample 6 so that it matches, and then inputs the signal into PZT scanner 7.

The following gives a more specific description. In cases where the input frequency into PLL 24 is 4.51 MHz, PLL 24 outputs 5.1 V. Therefore, probe-to-sample distance control signal 26 will set the resonant frequency of cantilever 3 to 290 kHz so that the next voltage value to be inputted into feedback circuit 25 becomes 5 V, which is the predetermined reference value. That is, the distance between probe 2 and sample 6 is controlled by probe-to-sample distance control signal 26 so that the resonant frequency of cantilever 3 becomes 290 kHz. Alternatively, for example, in cases where external oscillator 24 outputs an oscillating frequency of 4.19 MHz to multiplier 23, feedback circuit 25 sends probe-to-sample distance control signal 26 to PZT scanner 7 so that the resonant frequency of cantilever 3 becomes 310 kHz. Thus, feedback circuit 25 generates probe-to-sample distance control signal 26 in accordance with whether or not the input voltage inputted from PLL 24 matches the reference value (e.g., 5 V), thereby controlling the distance between probe 2 and sample 6. Moreover, this series of operations is carried out with the distance control feedback applied using external oscillator 22.

Thus, scanning atomic force microscope 20 according to the present embodiment appropriately regulates the external frequency to be produced by external oscillator 22 and thereby automatically changes the distance between probe 2 and sample 6. Then, by recording the distance and the value of action force, a force curve is obtained.

An effect of obtaining a force curve with the distance control feedback applied during the operation is the same as that which is obtained through scanning atomic force microscope 1 described with reference to FIG. 1 and, as such, is not described below. However, scanning atomic force microscope 1 and scanning atomic force microscope 20 differ from each other as follows: Scanning atomic force microscope 1 controls the distance between probe 2 and sample 6 in accordance with set value (Fts_set) 10 inputted as a voltage value into feedback circuit 5 and detects action force Fts between probe 2 and sample 6 placed at that distance; on the other hand, scanning atomic force microscope 20 makes a comparison between an input frequency and a reference frequency in feedback circuit 25 through a variable external frequency produced by external oscillator 22 and, in accordance with a result of the comparison, controls the distance between probe 2 and sample 6, and detects action force between probe 2 and sample 6 placed at that distance, thereby giving a force curve. Thus, regardless of whether the external input is a voltage value or a frequency, both scanning atomic force microscopes 1 and 20 give force curves with the distance control feedback applied. Therefore, the method for obtaining a force curve by using scanning atomic force microscope 20 can also overcome the aforementioned conventional problems. Moreover, the method for obtaining a force curve by using scanning atomic force microscope 20 allows precise and quick measurement of a force curve even in a region where probe 2 and sample 6 are very close to each other.

### Embodiment 3

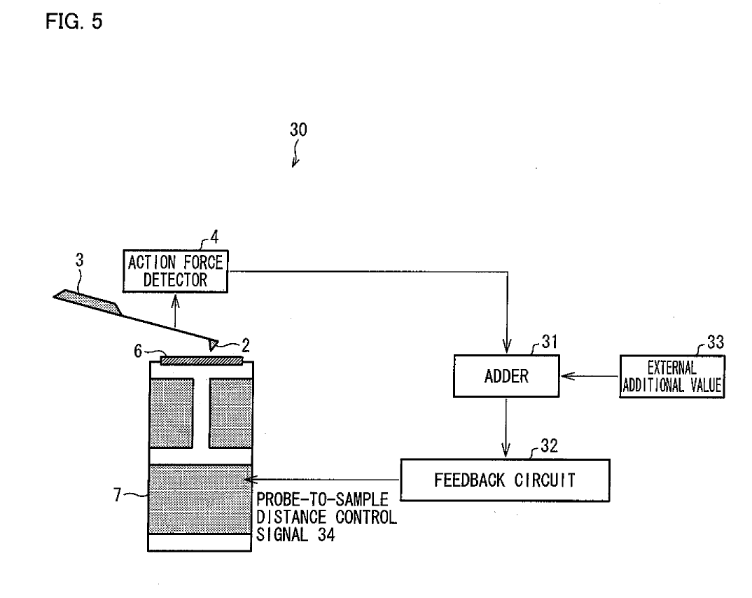

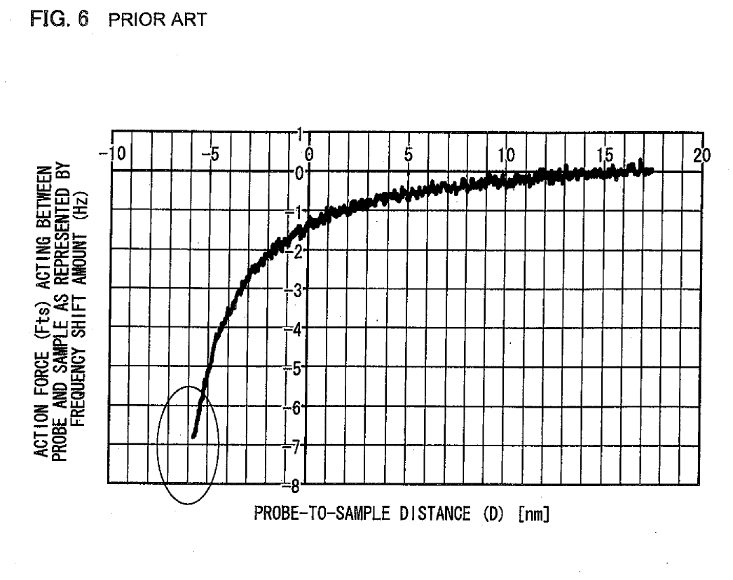

Embodiment 3 is described below with reference to FIG. 5. In FIG. 5, components identical to those described with reference to FIG. 1 are given the same reference numerals. Therefore, these components are not described in detail below.

FIG. 5 is a conceptual diagram of still another method for obtaining a force curve according to the present embodiment. Scanning atomic force microscope 30 includes: probe 2; cantilever 3, which supports probe 2; action force detector 4, which detects, as a resonant frequency, action force Fts acting between probe 2 and sample 6; PZT scanner 7, which uses a piezoelectric element to move sample 6 along the Z axis, the X axis, and the Y axis in accordance with probe-to-sample distance control signal 34 (control signal); adder 31; and feedback circuit 32.

Adder 31 receives variable external additional value 33 (set value) as a voltage value from an outside source and a variation in resonant frequency of cantilever 3 as a voltage value from action force detector 4. Then, adder 31 inputs the value of addition (additional value) of the voltage values into feedback circuit 32. It should be noted that set value (Fts_set) 10 according to scanning atomic force microscope 1 and external additional value 33 differ from each other as follows: set value (Fts_set) 10 specifies “how many hertz a resonant frequency variation representing action force Fts has”; on the other hand, external additional value 33 specifies “by how many hertz cantilever 3 shifts in resonant frequency variation from that point of time”.

Feedback circuit 32 generates probe-to-sample distance control signal 34 in accordance with the additional value inputted from adder 31, and then outputs the signal to PZT scanner 7.

A method for obtaining a force curve according to the present embodiment thus configured is described below with reference to FIG. 5. It should be noted that operations identical to those carried out in scanning atomic force microscope 1 described with reference to FIG. 1 are not described in detail below.

First, at the start of measurement, the distance between probe 2 and sample 6 is set so that probe 2 and sample 6 are placed at any usual distance from each other. Next, with probe 2 and sample 6 placed at that distance, action force detector 21 is used to detect action force Fts between probe 2 and sample 6. As mentioned above, since the action force Fts is not detected per se, a variation in resonant frequency of cantilever 3 is detected as a physical quantity that reflects the action force Fts. The variation in resonant frequency thus detected by action force detector 4 is converted into a voltage value in action force detector 4, and the voltage value is then inputted into adder 31. Adder 31 receives variable external additional value 33 as a voltage value from an outside source, together with a variation in resonant frequency of cantilever 3 as a voltage value. Then, adder 31 adds the two inputs and inputs the resulting additional value into feedback circuit 32.

Feedback circuit 32 generates probe-to-sample distance control signal 34 in accordance with the additional value inputted from adder 31. Probe-to-sample distance control signal 34 is inputted into PZT scanner 7, and PZT scanner 7 scans sample 6 in accordance with the signal and controls the distance between probe 2 and sample 6, so that action force between probe 2 and sample 6 placed at that distance is detected. Moreover, the detected value of the action force differs in frequency from the previously measured value by external additional value 33.

After that, the variation in resonant frequency of cantilever 3, which differs in resonant frequency by external additional value 33, is again detected by action force detector 4, and the detected value is inputted into adder 31. The subsequent operations are the same as those described above: The action force Fts is set in accordance with external additional value 33 thus inputted. Moreover, this series of operations is carried out with the distance control feedback applied using adder 31.

Thus, scanning atomic force microscope 30 according to the present embodiment appropriately regulates external additional value 33 to be inputted into adder 31 and thereby automatically changes the distance between probe 2 and sample 6. Then, by recording the value of the distance and the value of action force, a force curve is obtained.

An effect of obtaining a force curve with the distance control feedback applied during the operation is the same as that which is obtained through scanning atomic force microscope 1 described with reference to FIG. 1 and, as such, is not described below. However, scanning atomic force microscope 1 and scanning atomic force microscope 30 differ from each other as follows: As mentioned above, set value (Fts_set) 10 specifies “how many hertz action force Fts has”; on the other hand, external additional value 33 according to scanning atomic force microscope 30 specifies “by how many hertz cantilever 3 shifts in resonant frequency variation from that point of time”.

Thus, although scanning atomic force microscope 1 and scanning atomic force microscope 30 differ in input value from each other, both scanning atomic force microscope 1 and scanning atomic force microscope 30 give force curves with the distance control feedback applied. Therefore, the method for obtaining a force curve by using scanning atomic force microscope 30 can also overcome the aforementioned conventional problems. Moreover, the method for obtaining a force curve by using scanning atomic force microscope 20 allows precise and quick measurement of a force curve even in a region where probe 2 and sample 6 are very close to each other.

Thus far, various embodiments of the present invention have been described. It should be noted here that the following configuration can be added as still another embodiment. That is, in general, in the case of an attempt to obtain a force curve through a scanning atomic force microscope, action force (attractive force or repulsive force) acts between the probe and a sample. Moreover, in cases where a force curve is obtained with feedback applied, the feedback cannot be used unless the polarity of the action force (slope of the force curve) is constant. In this regard, the method for obtaining a force curve according to the present embodiment places particular emphasis on obtaining a force curve in a region where the probe and the sample are very close to each other (region that is very important in evaluating properties) and the slope of the force curve is constant. However, by detecting the slope of the force curve (derivative value) and reversing the polarity of the feedback at a point where the derivative value is zero, the method for obtaining a force curve according to the present embodiment can also be used in cases where there is a change in polarity.

The present invention is not limited to the description of the embodiments above, but may be altered by a skilled person within the scope of the claims. An embodiment based on a proper combination of technical means disclosed in different embodiments is encompassed in the technical scope of the present invention.

According to the method for measuring surface properties according to the present invention, it is preferable that the set value be set in correspondence with the desired physical quantity independently of the physical quantity measured immediately before the set value was set.

Thus, after the measured distance is controlled in correspondence with a set value and a desired physical quantity is measured, a set value corresponding to a new desired physical quantity can be set regardless of the former desired physical quantity. That is, a set value corresponding to the physical quantity that a user desires to measure can be set as it is. This allows the user to precisely and quickly measure his/her desired physical quantity.

According to the method for measuring surface properties according to the present invention, it is preferable that the set value be set in correspondence with a physical quantity that has been shifted by a desired amount from the physical quantity measured immediately before the set value was set.

Thus, the method for measuring surface properties according to the present invention allows the user to first confirm the physical quantity measured immediately before the set value was set and then set a new set value corresponding to a physical quantity that has been shifted by a desired amount from the physical quantity. That is, the user can proceed to measure a new physical quantity while confirming the state of the physical quantity measured.

This makes it possible to precisely and quickly measure a physical quantity without fear of a creep or a drift even in a region where the probe and the sample are very close to each other.

According to the method for measuring surface properties according to the present invention, it is preferable that the physical quantity be a variation in resonant frequency of a cantilever for supporting the probe, the variation in resonant frequency reflecting action force acting between the probe and the sample.

It is preferable that the method for measuring surface properties according to the present invention includes obtaining, in accordance with a relationship between the measured distance and the variation in resonant frequency, a force curve that represents a relationship between the measured distance and the action force.

Because the method for measuring surface properties according to the present invention cannot directly detect action force acting between the probe and the sample, a variation in resonant frequency of a cantilever for supporting the probe is detected as a physical quantity that reflects the action force. This allows the method for measuring surface properties according to the present invention to detect the action force through the variation in resonant frequency and, as a result, give a force curve that represents a relationship between the measured distance and the action force.

### (Others)

A method for measuring surface properties according to the present invention may be a method for measuring surface properties, which measures surface properties of a sample by placing a probe in close proximity to a surface of the sample, the method including the steps of: with distance control feedback applied to control a distance between the probe and the sample in accordance with a control signal, (i) setting the distance between the probe and the sample in accordance with the control signal; (ii) detecting a property value between the probe and the sample placed at the distance; and (iii) recording a relationship between the distance and the property value.

According to the foregoing configuration, the method for measuring surface properties according to the present invention allows, with distance control feedback applied to control a distance between the probe and the sample in accordance with a control signal, control of the distance between the probe and the sample, detection of a property value between the probe and the sample placed at the distance, and recording of a relationship between the distance and the property value. Therefore, for example, in such a case where a force curve is obtained, the distance can be automatically controlled by the control signal. This makes it possible obtain a steeply sloping force curve even in a region where such a force curve was not be able to be obtained by a conventional method (region that is very important in evaluating properties). Moreover, because the distance between the probe and the sample is automatically controlled in accordance with the control signal, a collision between the probe and the sample can be avoided. Further, even in the case of occurrence of an unintended change in distance due to a drift or the like, a collision can be avoided, because the distance between the probe and the sample is automatically controlled.

Further, in a region where the slope of a force curve is steep, the amount of change in distance D per unit time can be automatically reduced, because the distance is controlled in accordance with the control signal. This makes it possible to avoid a collision between the probe and the sample due to a creep. Further, because the amount of time to measure a force curve in a region about which no particular information is required can be reduced in accordance with the control signal, the total amount of measuring time can be reduced. Moreover, the reduction in measuring time makes it possible to reduce the frequency at which the distance is influenced by a temperature drift, a vibration drift, or the like, whereby a collision between the probe and the sample can be prevented.

Thus, provision of the foregoing configuration brings about an effect of allowing precise and quick measurement of the surface properties of the sample even in a region where the probe and the sample are very close to each other.

According to the method for measuring surface properties according to the present invention, the control signal may be generated in accordance with a set value of the property value.

Provision of the foregoing configuration allows generation of a control signal based on a set value of a property value and automatic control of the distance between the probe and the sample in accordance with the control signal. Then, the property value between the probe and the sample placed at that distance is set to a value that has been set. Therefore, for example, in such a case where a force curve is obtained, simply by inputting the set value of action force, the force curve can be precisely and quickly measured even in a region where the probe and the sample are very close to each other.

According to the method for measuring surface properties according to the present invention, the control signal may be generated in accordance with a value of addition of a detected value of the property value and an external input value inputted from an outside source.

Provision of the foregoing configuration allows calculation of a value of addition of a detected value of the property value and an external additional value, generation of a control signal based on the value of addition, and automatic control of the distance between the probe and the sample, simply by inputting the external additional value from an outside source. Therefore, for example, in such a case where a force curve is obtained, by appropriately inputting an external additional value, the force curve can be precisely and quickly measured even in a region where the probe and the sample are very close to each other.

According to the method for measuring surface properties according to the present invention, the control signal may be generated in accordance with a value calculated from an input frequency and a predetermined reference value, and the input frequency may be a frequency obtained by the frequency conversion of a resonant frequency of a cantilever supporting the probe by a variable external frequency produced by an external oscillator.

Provision of the foregoing configuration allows generation of a control signal in accordance with a frequency that is a sum of or difference between the input frequency and the reference frequency and automatic control of the distance between the probe and the sample, simply by inputting the external frequency from an outside source. Therefore, for example, in such a case where a force curve is obtained, by appropriately inputting an external frequency, the force curve can be precisely and quickly measured even in a region where the probe and the sample are very close to each other.

According to the method for measuring surface properties according to the present invention, the property value is action force, and a force curve may be obtained by recording a relationship between the distance and the action force.

Provision of the foregoing configuration allows detection of action force between the probe and the sample and recording of a relationship between the distance and the action force, thereby making it possible to obtain a force curve.

An apparatus for measuring surface properties according to the present invention may measure the surface properties of a sample by using any one of the methods for measuring surface properties described above.

According to the foregoing configuration, the apparatus for measuring surface properties according to the present invention can precisely and quickly measure the surface properties of a sample even in a region where the probe and the sample are very close to each other and, as a result, makes it possible to obtain local information about a surface of the sample that has not been obtainable so far.

A method for measuring surface properties according to the present invention may be a method for measuring surface properties, which measures surface properties of a sample by placing a probe in close proximity to a surface of the sample, the method including the steps of: with distance control feedback applied to control a distance between the probe and the sample in accordance with a control signal, (i) setting the distance between the probe and the sample in accordance with the control signal; (ii) detecting a property value between the probe and the sample placed at the distance; and (iii) recording a relationship between the distance and the property value. Thus, for example, in such a case where a force curve is obtained, this brings about an effect of allowing precise and quick measurement of the force curve even in a region where the probe and the sample are very close to each other, while avoiding a collision between the probe and the sample.

The apparatus for measuring surface properties according to the present invention may be configured to use the method for measuring surface properties. This makes it possible to precisely and quickly measure the surface properties of a sample even in a region where the probe and the sample are very close to each other, and to thereby obtain local information about a surface of the sample that has not been obtainable so far.

### INDUSTRIAL APPLICABILITY

The present invention can be applied to: a method for measuring surface properties, which measures the surface properties of a sample by placing a probe in close proximity to a surface of the sample; and an apparatus for measuring surface properties, which measures the surface properties of a sample by using such a method.

### REFERENCE SIGNS LIST

1, 20, 30 Scanning atomic force microscope
2 Probe
3 Cantilever
4, 21 Action force detector
5, 25, 32 Feedback circuit
6 Sample
7 PZT scanner
10 Set value
11, 26, 34 Probe-to-sample distance control signal (control signal)
15 Sample hold circuit
16 Analog switch
17 Capacitor
22 External oscillator
23 Multiplier
24 PLL
31 Adder
33 Externally additional value (set value)

1. A method for measuring surface properties, which measures surface properties of a sample by placing a probe in close proximity to a surface of the sample, the method comprising the steps of:
with distance control feedback applied so that a desired physical quantity to be measured that is attributed to an interaction between the probe and the sample is actually measured while changing a measured distance between the probe and the sample in accordance with a relationship between the desired physical quantity and the measured distance,
(i) setting a set value, corresponding to the desired physical quantity, which serves to change the measured distance; and
(ii) recording, for each set value thus set, a relationship between the measured distance changed by the set value set in the step (i) and a physical quantity measured with the probe and the sample placed at that measured distance.

2. The method as set forth in claim 1, wherein the set value is set in correspondence with the desired physical quantity independently of the physical quantity measured immediately before the set value was set.

3. The method as set forth in claim 1, wherein the set value is set in correspondence with a physical quantity that has been shifted by a desired amount from the physical quantity measured immediately before the set value was set.

4. The method as set forth in claim 1, wherein the physical quantity is a variation in resonant frequency of a cantilever for supporting the probe, the variation in resonant frequency reflecting action force acting between the probe and the sample.

5. The method as set forth in claim 1, comprising obtaining, in accordance with a relationship between the measured distance and the variation in resonant frequency, a force curve that represents a relationship between the measured distance and the action force.

6. An apparatus for measuring surface properties, which measures surface properties of a sample by placing a probe in close proximity to a surface of the sample, the apparatus comprising:
feedback control means for applying distance control feedback so that a desired quantity to be measured that is attributed to an interaction between the probe and the sample is actually measured while changing a measured distance between the probe and the sample in accordance with a relationship between the desired physical quantity and the measured distance;
setting means for setting a set value, corresponding to the desired physical quantity, which serves to change the measured distance; and
recording means for recording, for each set value thus set, a relationship between the measured distance changed by the set value set by the setting means and a physical quantity measured with the probe and the sample placed at that measured distance, with the feedback control means applying the distance control feedback.
